(19) United States
(12) Patent Application Publication
(10) Pub. No.: US 2003/0024734 A1
(43) Pub. Date: Feb. 6, 2003

(54) Surface mount electrical component assembly

(76) Inventors: David Ineson, Oakville, CT (US); Antonio Pinto, Madison, CT (US)

Correspondence Address: LAURA M. SLENZAK, SIEMENS CORPORATION, 186 WOOD AVENUE SOUTH, ISELIN, NJ, 08830, US

(21) Appl. No.: 09/923,496

(22) Filed: Aug. 6, 2001

(51) Int. Cl. H05K 1/16

(52) U.S. Cl. 174/260

(57) ABSTRACT

Disclosed herein are several embodiments of a surface mount electrical component assembly. One embodiment comprises a retainer, comprising a retaining base having on opening and an annular collar around said opening, for retaining an electrical component in the annular collar of said retainer; and a plurality of conductive ends, connected to the bottom of said retaining base, for creating an electrical connection to an electrical component. Further embodiments also comprise an electrical component, such as capacitors, surface mount crystals, resonators, chokes and inductors. In yet further embodiments, the surface mount electrical component assembly comprises a hollow retainer comprising a base portion with an opening thereon and a cylindrical portion having a closed end opposite the opening; an electrical component within the retainer, the electrical component having a plurality of electrical leads extending therefrom; and a plurality of conductive ends mounted to the base portion and adapted to receive the electrical leads in area of the opening.

### BACKGROUND OF THE INVENTION

1. Field of the Invention

The present invention relates to a surface mount electrical component assembly. Particularly, the present invention is directed to a surface mount electrical component assembly that may be used on a printed circuit board.

2. Description of Related Art

The use of surface mount electrolytic capacitors are known in the art. Typically, these surface mount capacitors are mounted on a circuit board that is itself mounted on an internal combustion engine. The printed circuit board may be used to control a mechanical or electronic device on the engine for improving vehicle emissions or performance. The surface mount capacitors are used for filtering of electrical currents, suppressing electric spikes and storing electrical energy.

In the prior art, surface mount capacitor assemblies have been provided which include a base mounted to a printed circuit board. Often times, a plurality of conductive pads are mounted to both the base and the circuit board to create the connection between the base and the printed circuit board. The conductive pads have electrical inputs to receive electrical leads from the bottom of the capacitor.

The prior art surface mount capacitor assemblies suffer from the chief disadvantage that the electrical connection between the electrical leads of the capacitor and the inputs on the conductive pads also serves as the mechanical connection of the capacitor to the circuit board. Because the circuit board is in a mechanically volatile environment, subject to high vibration levels, the lack of a firm mechanical connection can allow the capacitor to separate from the circuit board. To alleviate this problem, prior art systems have utilized adhesives, such as epoxies or hot-melt, or mechanical clips, to secure the capacitor to the printed circuit board. This adaptation adds expense to the assembly and diminishes the efficiency of the manufacturing process for such assemblies and circuit boards.

Accordingly, a need exists in the art for a surface mount electrical component assembly that provides separate mechanical and electrical connections between the electrical component and the circuit board.

### SUMMARY OF THE INVENTION

The purpose and advantages of the present invention will be set forth in and apparent from the description that follows, as well as will be learned by practice of the invention. Additional advantages of the invention will be realized and attained by the methods and systems particularly pointed out in the written description and claims hereof, as well as from the appended drawings.

A feature of an embodiment of the present invention is a retaining base comprising an annular collar that provides an interference fit for the electrical component. Another feature of an embodiment of the invention are conductive pads mounted to the retaining base for electrical connection to the electrical component.

Yet another feature of an embodiment of the present invention is a hollow retainer comprising a generally cylindrical body with a closed top end and an open end adjacent a base portion of the retainer. A further feature of an embodiment of the present invention are conductive pads under the base portion for electrical connection to the electrical component in the region of the open end. Yet another feature of an embodiment of the present invention is an electrical component retained in the hollow retainer in electrical connection with the conductive pads.

Further features of embodiments of the present invention include additional mounting pads provided under the retainer for enhanced connection of the retainer to a printed circuit board. Other features of embodiments of the present invention include conductive pads having crimped ends for gripping the outer periphery of the base portion of the retainer.

The advantage of embodiments of the present invention is that separate mechanical and electrical connections can be achieved. Hence, a surface mount electrical component assembly can be made inexpensively and efficiently that withstands high vibration levels and minimizes stress on the electrical connection.

In brief, the one embodiment of the invention is a surface mount electrical component assembly comprising a retainer comprising a retaining base having on opening and an annular collar around the opening; an electrical component retained in the annular collar of the retainer, the electrical component having a plurality of electrical leads thereon; and a plurality of conductive ends connected to the bottom of the retaining base, the conductive ends adapted to receive the electrical leads for electrical connection to the electrical component.

Briefly, another embodiment of the invention is a surface mount electrical component assembly comprising a hollow retainer comprising a base portion with an opening thereon and a cylindrical portion having a closed end opposite the opening; an electrical component within the retainer, the electrical component having a plurality of electrical leads extending therefrom; and a plurality of conductive ends mounted to the base portion and adapted to receive the electrical leads in area of the opening.

Briefly, yet another embodiment of the invention is a printed circuit board for mounting a surface mount electrical component, the circuit board comprising a plurality of conductive ends in electrical connection with the circuit board, the ends having electrical connectors adapted to receive electrical leads from the surface mount electrical component; a retainer comprising a retaining base having on opening and an annular collar around the opening; and wherein the plurality of conductive ends are connected to the bottom of the retaining base, and wherein the electrical connectors of the conductive ends are adapted to receive the electrical leads in the area of the opening.

Briefly, yet another embodiment of the invention is a surface mount electrical component assembly comprising a retainer, comprising a retaining base having on opening and an annular collar around the opening, for retaining an electrical component in the annular collar of the retainer; and a plurality of conductive ends, connected to the bottom of the retaining base, for creating an electrical connection to an electrical component.

It is to be understood that both the foregoing general description and the following detailed description are exemplary and are intended to provide further explanation of the invention claimed.

The accompanying drawing, which is incorporated in and constitutes part of this specification, is included to illustrate and provide a further understanding of the method and system of the invention. Together with the description, the drawing serves to explain the principles of the invention.

### BRIEF DESCRIPTION OF THE DRAWINGS

FIG. 1 is a top perspective view of an embodiment of a surface mount electrical component assembly in accordance with the invention.

FIG. 2 is a bottom perspective view of the embodiment shown in FIG. 1.

FIG. 3 is a top perspective view of another embodiment of a surface mount electrical component assembly in accordance with the invention.

FIG. 4 is a bottom perspective view of the embodiment shown in FIG. 3.

FIG. 5 is a top perspective view of another embodiment of a surface mount electrical component assembly in accordance with the invention.

FIG. 6 is a bottom perspective view of the embodiment shown in FIG. 5.

FIG. 7 is a top perspective view of another embodiment of a surface mount electrical component assembly in accordance with the invention.

FIG. 8 is a bottom perspective view of the embodiment shown in FIG. 7.

FIG. 9 is an exploded view of the embodiment shown in FIG. 7.

FIG. 10 is a top perspective view of another embodiment of a surface mount electrical component assembly in accordance with the invention.

FIG. 11 is a bottom perspective view of the embodiment shown in FIG. 10.

FIG. 12 is an exploded view of another embodiment of a surface mount electrical component assembly in accordance with the invention.

FIG. 13 is a bottom perspective view of another embodiment of a surface mount electrical component assembly in accordance with the invention.

FIGS. 14A is a top plan view of another embodiment of a surface mount electrical component assembly in accordance with the invention.

FIGS. 14B is a top plan view of another embodiment of a surface mount electrical component assembly in accordance with the invention.

FIG. 15 is a cross sectional view of another embodiment of a surface mount electrical assembly in accordance with the present invention.

FIG. 16 is a cross sectional view of another embodiment of a surface mount electrical assembly in accordance with the present invention.

### DETAILED DESCRIPTION OF THE PREFERRED EMBODIMENT

Reference will now be made in detail to the present preferred embodiments of the invention, examples of which are illustrated in the accompanying drawings. The preferred embodiments of the invention will be described in conjunction with the detailed descriptions provided below.

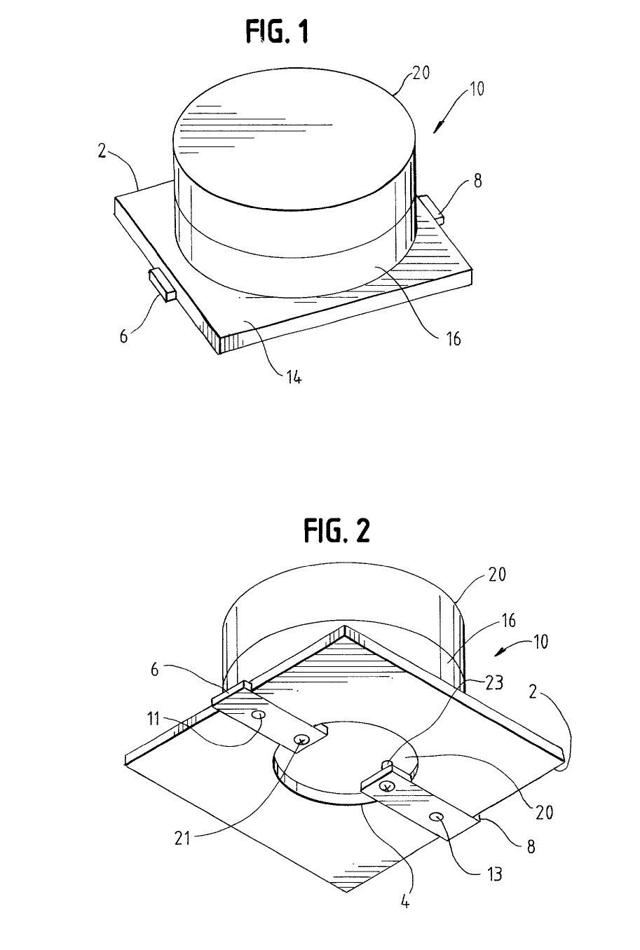

The surface mount electrical component assemblies presented herein may be used for any application where it is desirable to provide a surface mount electrical component. The present invention is particularly suited for, but is not limited to, surface mount electrical components used in connection with automotive systems, such as surface mount electrical components used in connection with a printed circuit board on an internal combustion engine. For purpose of explanation and illustration, and not limitation, exemplary embodiments of the assembly in accordance with the invention are shown in FIGS. 1-14. It should be understood, and it is intended that the various embodiments presented herein are susceptible to modification and adaptation based upon the needs of the users, and the features and advantages described in reference to any one Figure or Figures may be applied to other Figures showing alternative embodiments.

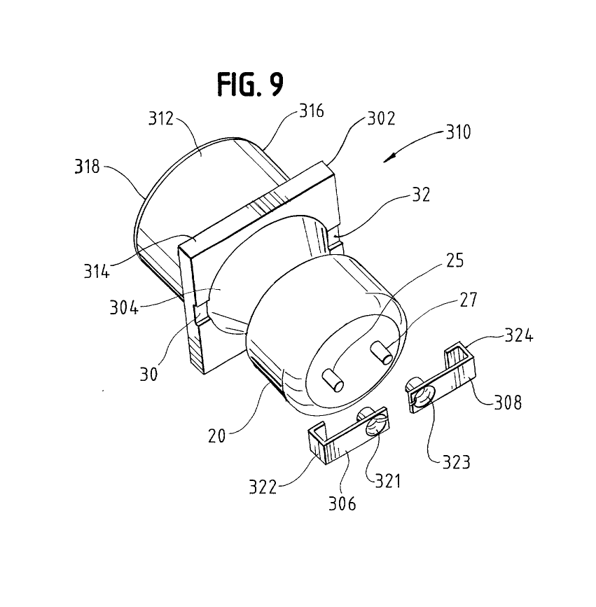

As shown in FIGS. 1 and 2, one embodiment of the surface mount electrical component assembly 10 generally includes a retaining base 2 having an opening 4, a plurality of conductive pads 6, 8 connected to the bottom of the base 2 and adapted to receive electrical leads from an electrical component 20, and an electrical component 20 retained in the opening 4 of the base 2 having a plurality of electrical leads 25, 27 (see FIG. 9) for electrical connection to the conductive pads 6, 8.

In more detail, according to the embodiment shown in FIGS. 1 and 2, the assembly 10 comprises a retaining base 2. The retaining base 2 can be made of a non-conductive material capable of being injection molded, including but not limited to, thermoset or thermoplastic resin. The retaining base comprises a base portion 14 to be mounted to a printed circuit board (not shown) or other electrical assembly wherein a surface mount electrical component is called for. Although the base portion 14 of the retaining base 2 of the present embodiment has a generally square shape, the base portion 14 may assume any useful shape depending upon the needs of the user. For example, circular, rectangular, or other polygons or irregular shapes may be used without departing from the claims or the scope of the invention. In the preferred embodiment, the base portion 14 is approximately 0.020 to 0.080 inches thick to accommodate a typical printed circuit board used in connection with an internal combustion engine. However, the base may be thicker or thinner depending upon the needs of the user.

The retaining base 2 further comprises an opening 4 about the center of the base portion 14. In the preferred embodiment, the opening 4 has a circular shape having a diameter slightly larger than the distance between electrical leads extending from the bottom of the electrical component 20. However, the present invention is not limited to circular openings, and any opening 4 in the area of the electrical leads of the electrical component 20 will suffice. For example, other embodiments within the scope of the invention may comprise rectangular openings in the base portion, extending from one electrical lead to the other. The size and shape of the opening 4 need only permit the electrical leads to reach the conductive pads 6, 8. Aside from that, the actual size and shape of the opening 4 will be dictated by factors such as costs, the availability of molds, ability to function with different size electrical components, and other design criteria.

The retaining base 2 of the present embodiment further comprises an annular collar 16 extending perpendicular to the plane of the base portion 14 for retaining the electrical component 20. In the preferred embodiment, the annular collar 16 is centered on the base portion 14 to allow the retaining base 2 to retain a generally cylindrical electrical component 20. The annular collar 16 may extend from about the circumference of the opening 4, or may extend from an area outside of the perimeter of the opening 4 so that the base portion 14 around the opening 4 forms a seat for the electrical component 20. The annular collar 16 is preferably made integral with the base portion 14 to provide a single retaining base 2. In the preferred embodiment, the annular collar 16 rises approximately half way up the electrical component 20. The annular collar has a thickness of approximately 0.020 to 0.040 inches in the preferred embodiment, although it should be understood that the principle of the invention does not depend on any particular thickness, and such matters will depend upon design criteria such as the size of the electrical component 20, the material used to form the retaining base 2, costs of manufacture, and the amount of vibration reduction needed to be achieved by the assembly. The inner diameter of the annular collar 16 is just larger than the diameter of the electrical component 20 to provide a frictional fit between the electrical component 20 and the annular collar 16. In alternative embodiments, the annular collar 16 may be made of a stiff, resilient insulator, such as rubber, to enhance the frictional fit between the collar 16 and the electrical component 20. In further embodiments, the annular collar could be molded out of rubber over the base 14 in a two stage injection molding machine.

The present embodiment further comprises a pair of conductive pads 6, 8 connected to the bottom of the base portion 14 and adapted to receive the electrical leads of the electrical component 20. The conductive pads 6, 8 are adapted to receive electrical leads from the electrical component 20 in connectors 21, 23. In the preferred embodiments, the conductive pads 6, 8 are made of tin plated copper alloy. However, the pads can be made out of any conductive material, preferably a material that can be formed into a thin sheet and soldered. The conductive pads 6, 8 are placed in electrical contact with the printed circuit board (not shown). In the preferred embodiment, before the electrical component is placed on a printed circuit board, a paste consisting of fine solder particles and flux is applied to a copper or tin coated copper area on the printed circuit board. This paste is applied where conductive pads 6 and 8 will rest when the electrical component is placed onto the printed circuit board. An application of heat will melt the fine solder particles causing the solder paste to flow and bond the conductive pads 6 and 8 to the copper or tin coated copper area on the printed circuit board. However, this is not the only method of bonding and other methods of bonding known in the art may be used. In the present embodiment, the conductive pads 6, 8 are connected to the retaining base 2 via protruding bosses 11, 13 protruding from the bottom of the base portion 14 of the retaining base 2. The bosses 11, 13 are inserted into holes in the pads 6, 8 and secured through molding or heat-staking, or other means of mechanical connection known to those with skill in the art. In the present embodiment, the conductive pads 6, 8 have one end extending into the opening 4 so that the connectors 21, 23 can receive the electrical leads 25, 27 of the electrical component 20 in the opening 4. The pads 6, 8 of the present embodiment extend from the connector end in the opening 4 to just outside the periphery of the base portion 14.

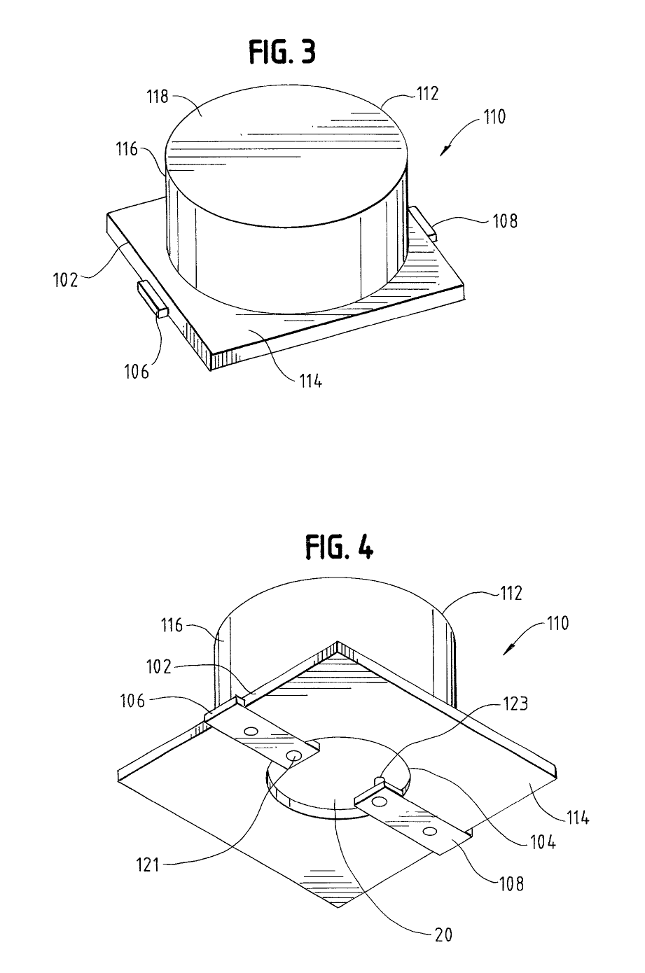

FIGS. 3 and 4 depict yet another embodiment of the surface mount electrical component assembly of the present invention. This embodiment is substantially the same as the embodiment shown in FIGS. 1 and 2 except the retaining base 2 takes an alternative form. In the present embodiment, the assembly comprises a hollow retainer 102 comprising a base portion 114 with an opening 104 therein. The retainer 102 further comprises a cylindrical portion 1 12 having a cylindrical wall 116 and a closed end 118 opposite the opening 104. The assembly of the present embodiment further comprises conductive pads 106, 108 which are similar in all respects to the pads 6, 8 described in relation to FIGS. 1 and 2. In this embodiment, the electrical component 20 is retained within and partially encapsulated by the hollow retainer 102. It should be apparent that the adaptations and modifications to the embodiment described in FIGS. 1 and 2 can apply also to the present embodiment. The hollow retainer 102 is designed with an internal cavity permitting snug fit of the electrical component 20. The hollow retainer 102 can be made of any size and shape depending upon the size and shape of the electrical component or other design criteria.

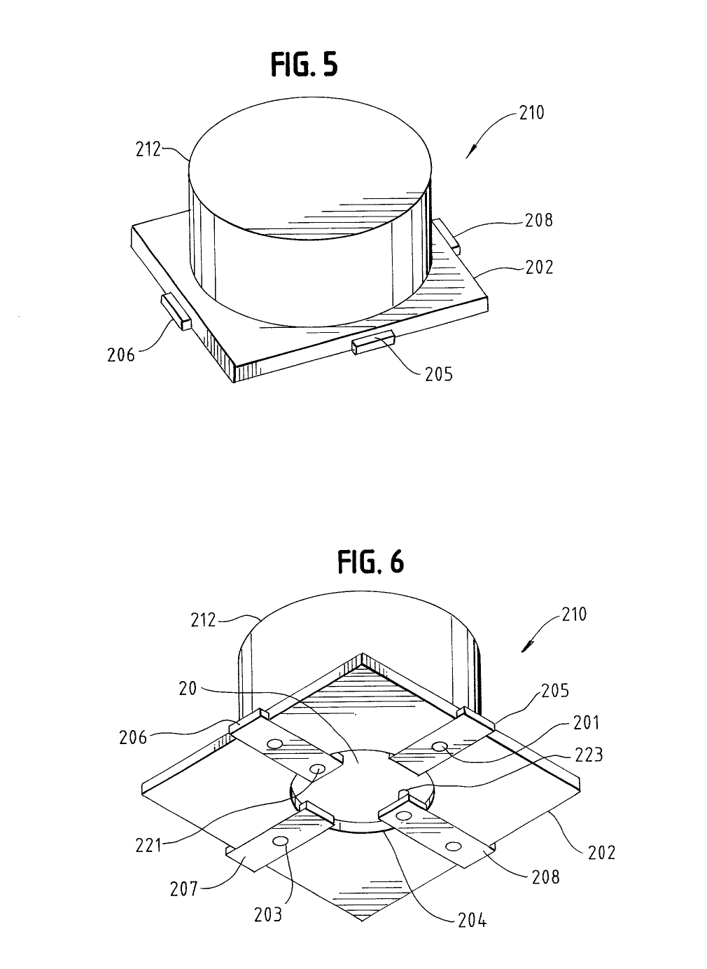

FIGS. 5 and 6 depict yet another embodiment of the present invention. In FIGS. 5 and 6, additional support and retention pads 205, 207 are used to enhance the connection between the retainer 202 and the printed circuit board (not shown). The additional pads 205, 207 are connected to the bottom of the base portion 214 of the retainer 202 by molding or heat staking additional protruding bosses 201, 203 protruding from the bottom of the base portion 214. Alternatively, the additional support and retention pads 205, 207 may be connected to the retainer 202 via any suitable connection means, including those described herein. Although the present embodiment is shown with the hollow retainer 202 depicted in FIGS. 3 and 4, it is intended that additional support and retention pads 205, 207 may be utilized with any of the embodiments of the invention, including, without limitation, the embodiment described in FIGS. 1 and 2.

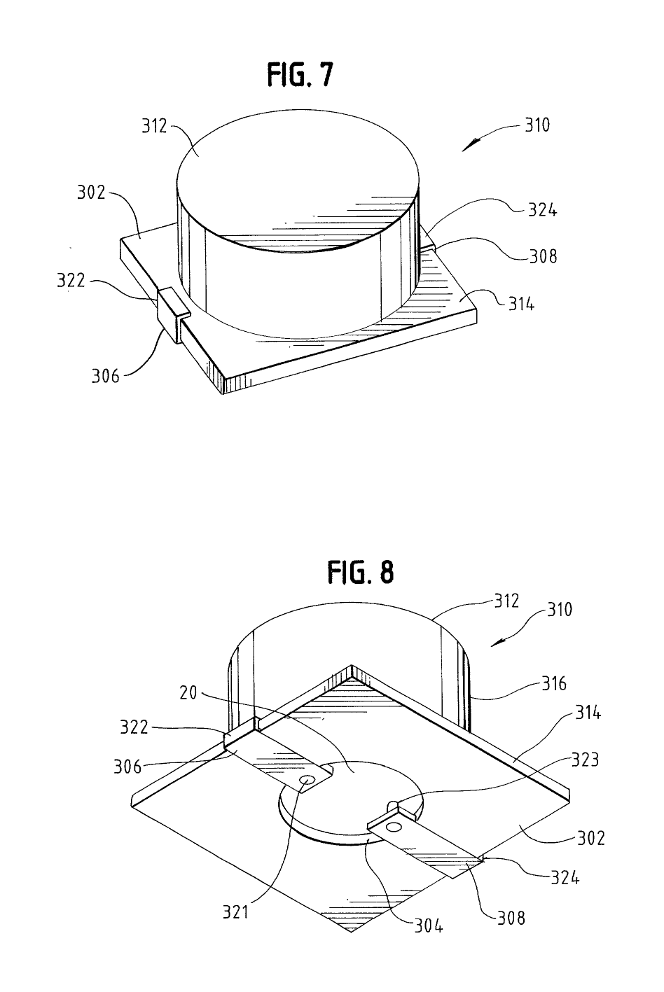

FIGS. 7 through 9 depict yet another embodiment of the present invention. This embodiment is described in relation to a hollow retainer 302, although it should be apparent and it is intended that the modifications of the present embodiment may be adapted to the retaining base 2 depicted in FIGS. 1 and 2, or any other retaining base in accordance with the present invention, without departing from the scope of the claims. The principal modification of the present embodiment is an alternative means for connecting the retainer 302 to the conductive pads 306, 308. The bottom of the base portion 314 includes channels 30, 32 to accommodate the conductive pads 306, 308. The depth of the channels 30, 32 is preferably equal to the width of the conductive pads 306, 308. In this embodiment, the conductive pads 306, 308 extend past the perimeter of the base portion 314 of the retainer 302, and are bent upwards to form gripping areas 322, 324. The gripping areas 322, 324 crimp around the base portion 314 of the retainer 302 to hold the retainer 302 in place. In the preferred embodiment, the gripping areas 322, 324 are flexible and resilient so that they can be bent outward, away from the retainer 302 and will snap into place around the base portion 314. Alternatively, one or both gripping areas 322, 324 may be tapered at their top surface to permit one-way insertion of the retainer 302 into the hold of the pads 306, 308. In this way, the base portion 314 of the retainer 302 may be inserted into one end, for example 322, and the retainer 302 (with the electrical component 20 inside) can be pressed down into position at the other end 324, locking the retainer 302 in place. This embodiment presents the additional advantage of being able to first connect the pads 306, 308 to a printed circuit board while the remainder of the assembly 310 can be easily removed, for example, to replace a bad electrical component 20.

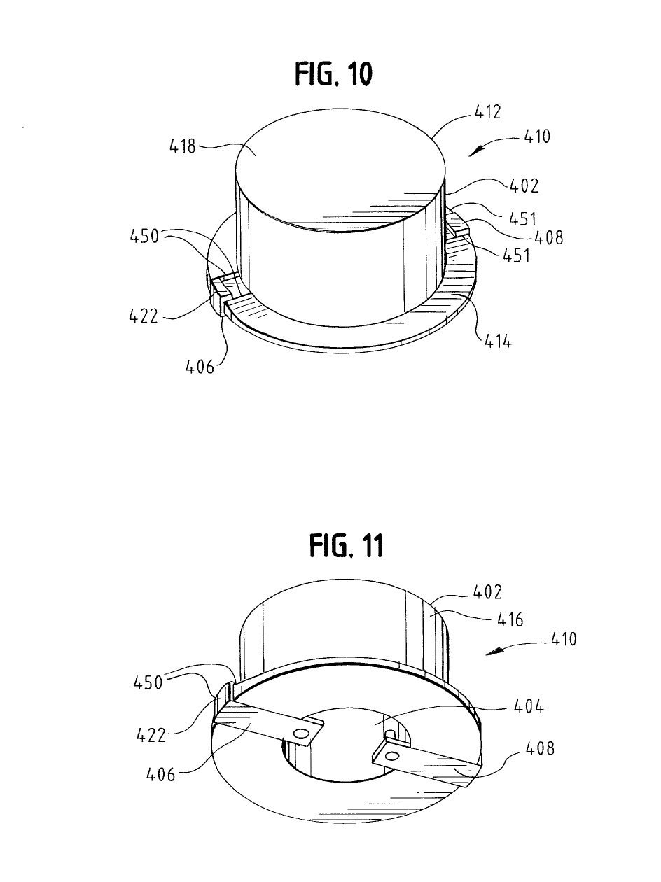

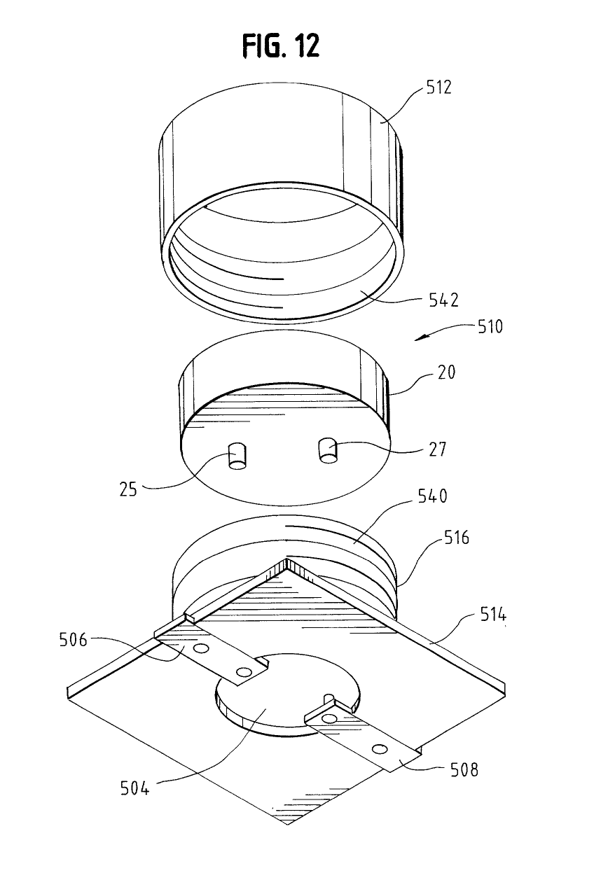

FIGS. 10 and 11 depict yet another embodiment of the invention utilizing an alternative means for connecting the conductive pads to the retainer. In this embodiment 410, the base portion 414 is circular in shape. Although the present means is described in relation to an embodiment utilizing a hollow retainer 402, the present description is not so limited and may apply to all forms and shapes of retainers described herein and their equivalents without departing from the scope of the claimed invention. The base portion 414 includes pairs of elevated stops 450, 451 located at opposite ends of the base portion 414. The conductive pads 406, 408 are similar in all respects to the pads described with respect to FIGS. 7 through 9. In the present embodiment, the retainer 402 is slid between the gripping areas 422, 424 of the conductive pads 406, 408 and turned until the gripping portions 422, 424 slide over and settle between the elevated stops 450, 451. The elevated stops 450, 451 are tapered to permit the retainer 402 to be locked through rotation in either a clockwise or counterclockwise direction. The same configuration may also be used in connection with flexible, resilient gripping areas 422, 424 so that, as described earlier, the retainer 402 can be inserted with a first gripping area 422 between the pair of elevated stops 450, and the second gripping area 424 can be bent backwards to receive the retainer 402 and snap into place between the pair of elevated stops 451.

FIG. 12 depicts yet another embodiment of the present invention. This embodiment comprises a two-piece retainer 510 comprising a base portion 514 having an annular collar 516 extending perpendicular to the plane of the base portion 514 for retaining the electrical component 20. The annular collar 516 includes external threads 540. The retainer 510 further includes a cover portion 512 having internal threads 542. In operation, the base portion 514 with its threaded annular collar 516 may be used alone, essentially in accordance with the embodiment described in FIGS. 1 and 2. If additional vibration control is desired, or other design criteria merit a more complete enclosure of an electrical component, the cover portion 512 may be screwed over the annular collar 516 by engaging the threading 540 and 542. The cover portion 512 may be lined in its interior with an appropriate vibration damping material, such as a resilient filler, ribs, or a cantilevered arm that presses down on the capacitor as the cover 512 is screwed over collar 516. However, other methods known in the art may also be used to dampen vibration and provide a snug fit for the electrical component. This embodiment has the further advantage that a faulty electrical component may be easily replaced without having to disconnect the base portion 514 from its connection (via the conductive pads 506, 508) to a circuit board.

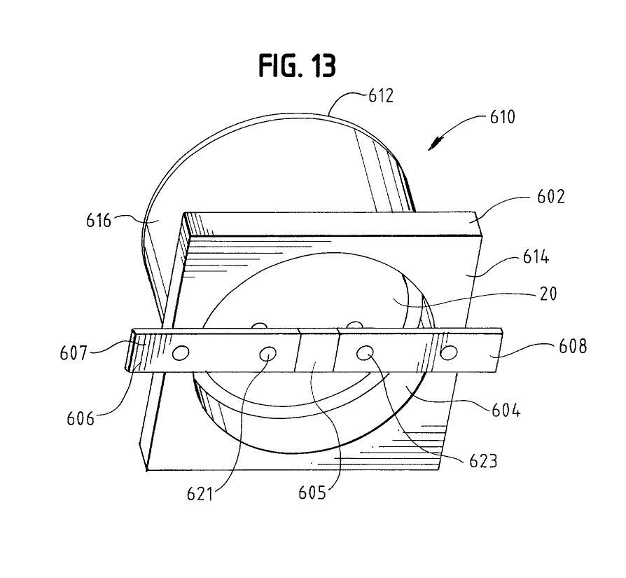

FIG. 13 depicts an alternative embodiment of the present invention. In this embodiment 610, a single conductive pad 607 extending from one end of the retaining base to the other, may be connected to the bottom of the base portion 614. The single pad 607 has two conductive ends 606, 608 separated by an insulating section 605. This embodiment is described in relation to a hollow retainer 602, although it should be apparent and it is intended that the modifications of the present embodiment may be adapted to the retaining base 2 depicted in FIGS. 1 and 2, or any other retaining base in accordance with the present invention, without departing from the scope of the claims.

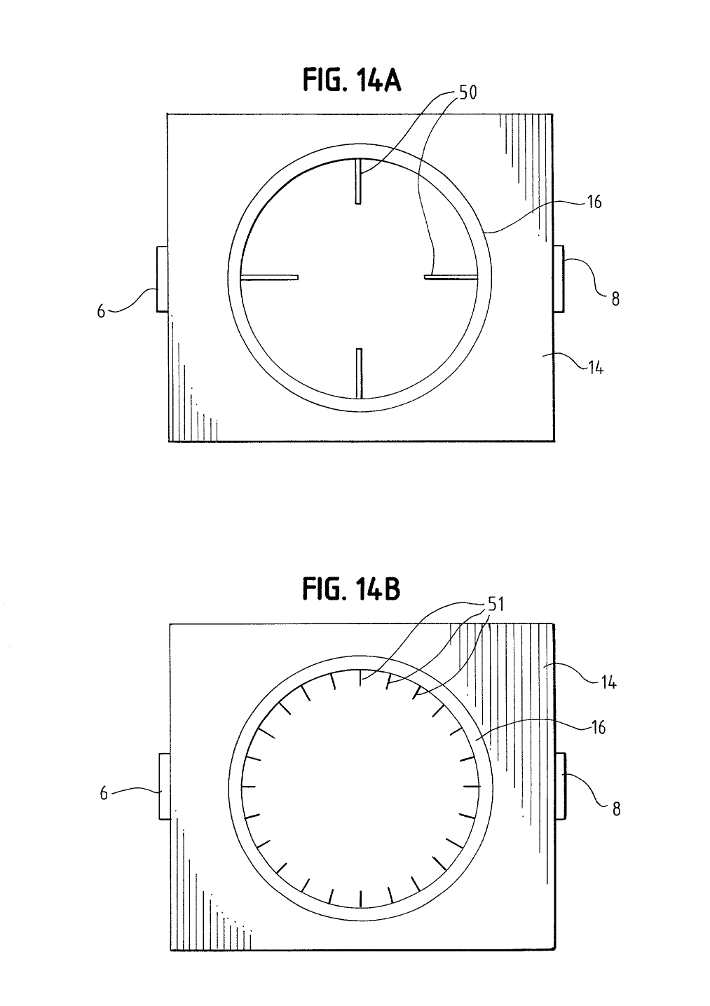

FIGS. 14A and 14B demonstrate additional embodiments wherein the annular collar has a series of ribs that would crush slightly when the electrical component is assembled to the base. The interference between the ribs retain the electrical component. In FIG. 14A, the annular collar 16 has a plurality of radially extending ribs 50 to bias the component in the collar 16. In alternative embodiments, such as FIG. 14B, the ribs comprise smaller but more numerous serrations 51 to enhance the gripping capacity of the collar 16. Each of the features of the above embodiments are interchangeable and may be used individually or combined in groups of two or more together in a single embodiment.

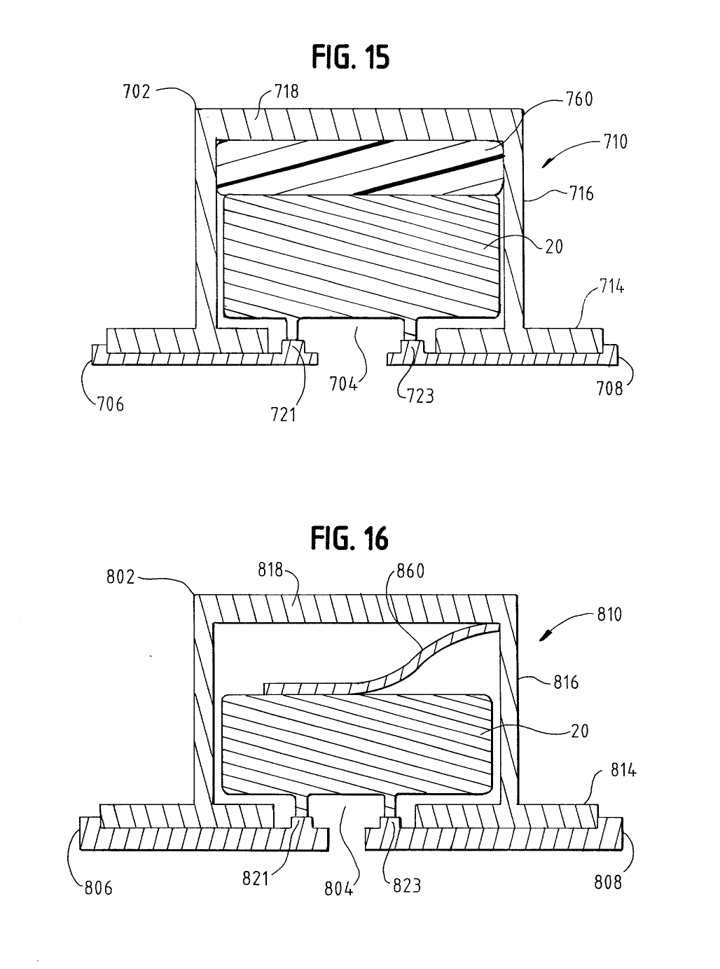

FIG. 15 depicts an alternative embodiment wherein the hollow retainer 702 includes some resilient filler material 760 to enhance the retention of the electrical component 20. Such filler material 760 may include, but is not limited to foam rubber, silicone, or urethane elastomer. However, the hollow retainer may be adapted using other methods to provide a snug fit for the capacitor, depending on the needs of the user. It should be apparent that the features described in FIG. 15 are adaptable to the hollow retainer and the retaining cap embodiments of the present invention.

FIG. 16 depicts an alternative embodiment wherein the hollow retainer 802 includes a cantilevered arm 860 to enhance the retention of the electrical component 20. The cantilevered arm 860 is supported at one end near the top of the hollow retainer 802 and extends down toward the component 20. The cantilevered arm 860 exerts a biasing force on the component 20 to enhance the fit in the retainer 802. It should be apparent that the features described in FIG. 16 are adaptable to the hollow retainer and the retaining cap embodiments of the present invention.

It will be apparent to those skilled in the art that various modifications and variations can be made in the method and system of the present invention without departing from the spirit or scope of the invention. Thus, it is intended that the present invention include modifications and variations that are within the scope of the appended claims and their equivalents.

What is claimed is:

1. A surface mount electrical component assembly comprising:
a retainer comprising a retaining base having on opening and an annular collar around said opening;
an electrical component retained in the annular collar of said retainer, said electrical component having a plurality of electrical leads thereon; and
a plurality of conductive ends connected to the bottom of said retaining base, said conductive ends adapted to receive said electrical leads for electrical connection to said electrical component.

2. The surface mount electrical component assembly of claim 1 wherein each of said plurality of conductive ends comprises a conductive pad.

3. The surface mount electrical component assembly of claim 1 wherein said annular collar has external threading.

4. The surface mount electrical component assembly of claim 3 further comprising a retaining cap.

5. The surface mount electrical component assembly of claim 4 wherein said retaining cap has internal threading.

6. The surface mount electrical component assembly of claim 1 wherein said annular collar is made of a stiff resilient insulator.

7. The surface mount electrical component assembly of claim 6 wherein said annular collar is made of rubber.

8. The surface mount electrical component assembly of claim 1 further comprising means for enhancing the retention of the electrical component in said annular collar.

9. The surface mount electrical component assembly of claim 8 wherein said means for enhancing the retention of the electrical component is a series of ribs.

10. The surface mount electrical component assembly of claim 1 further comprising a plurality of non-conductive pads connected to the bottom of the retaining base for connection to a printed circuit board.

11. The surface mount electrical component assembly of claim 1 wherein said conductive ends are molded to the retaining base.

12. The surface mount electrical component assembly of claim 1 wherein said conductive ends have crimped outer portions for gripping the periphery of said retaining base.

13. The surface mount electrical component assembly of claim 12 wherein said retaining base has a circular shape and includes a pair of elevated stops at diametrically opposed positions thereon, and wherein the crimped outer portions of the conductive ends grip the retaining base between said elevated stops.

14. The surface mount electrical component assembly of claim 13 wherein said elevated stops are tapered to permit the retainer to be locked through rotation in either a clockwise or counterclockwise direction.

15. The surface mount electrical component assembly of claim 1 wherein said plurality of conductive ends are opposite ends of a strip comprising the two conductive ends separated by an insulating area.

16. A surface mount electrical component assembly comprising:
a hollow retainer comprising a base portion with an opening thereon and a cylindrical portion having a closed end opposite the opening;
an electrical component within said retainer, said electrical component having a plurality of electrical leads extending therefrom; and
a plurality of conductive ends mounted to said base portion and adapted to receive said electrical leads in area of the opening.

17. The surface mount electrical component assembly of claim 16 wherein each of said plurality of conductive ends comprises a conductive pad.

18. The surface mount electrical component assembly of claim 16 further comprising means for enhancing the retention of the electrical component in said hollow retainer.

19. The surface mount electrical component assembly of claim 18 wherein said means for enhancing the retention of the electrical component is a resilient filler material.

20. The surface mount electrical component assembly of claim 19 wherein said resilient filler material is selected from the group consisting of elastic filler, foam rubber, silicone, and urethane elastomer.

21. The surface mount electrical component assembly of claim 18 wherein said means for enhancing the retention of the electrical component is radially extending ribs.

22. The surface mount electrical component assembly of claim 18 wherein said means for enhancing the retention of the electrical component is a cantilevered arm.

23. The surface mount electrical component assembly of claim 16 further comprising a plurality of non-conductive pads connected to the bottom of the base portion for connection to a printed circuit board.

24. The surface mount electrical component assembly of claim 16 wherein said conductive ends are molded to the base portion.

25. The surface mount electrical component assembly of claim 16 wherein said conductive ends have crimped outer portions for gripping the periphery of said base portion.

26. The surface mount electrical component assembly of claim 25 wherein said base portion has a circular shape and includes a pair of elevated stops at diametrically opposed positions thereon, and wherein the crimped outer portions of the conductive ends grip the base portion between said elevated stops.

27. The surface mount electrical component assembly of claim 26 wherein said elevated stops are tapered to permit the retainer to be locked through rotation in either a clockwise or counterclockwise direction.

28. The surface mount electrical component assembly of claim 16 wherein each of said conductive ends has a hole therein, and wherein the base portion includes a plurality of protruding bosses inserted in said holes.

29. The surface mount electrical component assembly of claim 16 wherein said plurality of conductive ends are opposite ends of a strip comprising the two conductive ends separated by an insulating area.

30. A printed circuit board for mounting a surface mount electrical component, said circuit board comprising:
a plurality of conductive ends in electrical connection with said circuit board, said ends having electrical connectors adapted to receive electrical leads from said surface mount electrical component;
a retainer comprising a retaining base having on opening and an annular collar around said opening; and
wherein said plurality of conductive ends are connected to the bottom of said retaining base, and wherein said electrical connectors of said conductive ends are adapted to receive said electrical leads in the area of said opening.

31. The printed circuit board of claim 30 wherein each of said plurality of conductive ends comprises a conductive pad.

32. The printed circuit board of claim 30 wherein said annular collar has external threading.

33. The printed circuit board of claim 30 further comprising a retaining cap.

34. The printed circuit board of claim 33 wherein said retaining cap has internal threading.

35. The printed circuit board of claim 30 wherein said annular collar is made of a stiff resilient insulator.

36. The surface mount electrical component assembly of claim 35 wherein said annular collar is made of rubber.

37. The printed circuit board of claim 30 further comprising means for enhancing the retention of the electrical component in said annular collar.

38. The printed circuit board of claim 37 wherein said means for enhancing the retention of the electrical component is a series of ribs.

39. The printed circuit board of claim 30 further comprising a plurality of non-conductive pads connected to the bottom of the retaining base for connection to the printed circuit board.

40. The printed circuit board of claim 30 wherein said conductive ends are molded to the retaining base.

41. The printed circuit board of claim 30 wherein said conductive ends have crimped outer portions for gripping the periphery of said retaining base.

42. The printed circuit board of claim 30 wherein said plurality of conductive ends are opposite ends of a strip comprising the two conductive ends separated by an insulating area.

43. A surface mount electrical component assembly comprising:
a retainer, comprising a retaining base having on opening and an annular collar around said opening, for retaining an electrical component in the annular collar of said retainer; and
a plurality of conductive ends, connected to the bottom of said retaining base, for creating an electrical connection to an electrical component.

44. The surface mount electrical component assembly of claim 43 further comprising an electrical component.

45. The surface mount electrical component assembly of claim 43 wherein each of said plurality of conductive ends comprises a conductive pad.

46. The surface mount electrical component assembly of claim 43 wherein the electrical component is a capacitor.

47. The surface mount electrical component assembly of claim 43 wherein the electrical component is a surface mount crystal.

48. The surface mount electrical component assembly of claim 43 wherein the electrical component is a resonator.

49. The surface mount electrical component assembly of claim 43 wherein the electrical component is a choke.

50. The surface mount electrical component assembly of claim 43 wherein the electrical component is an inductor.

51. The surface mount electrical component assembly of claim 43 wherein said annular collar has external threading.

52. The surface mount electrical component assembly of claim 51 further comprising a retaining cap.

53. The surface mount electrical component assembly of claim 52 wherein said retaining cap has internal threading.

54. The surface mount electrical component assembly of claim 43 wherein said annular collar is made of a stiff resilient insulator.

55. The surface mount electrical component assembly of claim 54 wherein said annular collar is made of rubber.

56. The surface mount electrical component assembly of claim 43 further comprising means for enhancing the retention of an electrical component in said annular collar.

57. The surface mount electrical component assembly of claim 56 wherein such means for enhancing the retention of the electrical component is a series of ribs.

58. The surface mount electrical component assembly of claim 43 further comprising a plurality of non-conductive pads connected to the bottom of the retaining base for connection to a printed circuit board.

59. The surface mount electrical component assembly of claim 43 wherein said conductive ends are molded to the retaining base.

60. The surface mount electrical component assembly of claim 43 wherein said conductive ends have crimped outer portions for gripping the periphery of said retaining base.

61. The surface mount electrical component assembly of claim 60 wherein said retaining base has a circular shape and includes a pair of elevated stops at diametrically opposed positions thereon, and wherein the crimped outer portions of the conductive ends grip the retaining base between said elevated stops.

62. The surface mount electrical component assembly of claim 61 wherein said elevated stops are tapered to permit the retainer to be locked through rotation in either a clockwise or counterclockwise direction.

63. The surface mount electrical component assembly of claim 43 wherein said plurality of conductive ends are opposite ends of a strip comprising the two conductive ends separated by an insulating area.
